(19) United States
(12) Patent Application Publication
(10) Pub. No.: US 2026/0021655 A1
(43) Pub. Date: Jan. 22, 2026

(54) METHOD OF SEPARATING CARRIER AND METHOD OF MANUFACTURING PACKAGED DEVICES

(71) Applicant: DISCO CORPORATION, Tokyo (JP)

(72) Inventors: Hayato KIUCHI, Tokyo (JP); Yoshihiro OMURO, Tokyo (JP); Takatoshi SAKURAI, Tokyo (JP); Shinichiro HORI, Tokyo (JP); Yukihisa KAKUTA, Tokyo (JP); Hiroyuki HIRAGA, Tokyo (JP)

(21) Appl. No.: 19/240,097

(22) Filed: Jun. 17, 2025

(30) Foreign Application Priority Data
Jul. 16, 2024 (JP) 2024-113430
Apr. 17, 2025 (JP) 2025-067944

(51) Int. Cl. B32B 43/00; H01L 21/78

(52) U.S. Cl. CPC B32B 43/006; B32B 2457/14; H01L 21/78

(57) ABSTRACT

A method of separating a carrier bonded to a workpiece by a temporary adhesive layer from the workpiece includes forming a separation initiating point in the temporary adhesive layer by inserting a protrusive member into the temporary adhesive layer in such a manner that the protrusive member enters between the workpiece and the carrier and, after the separation initiating point has been formed in the temporary adhesive layer, applying external forces respectively to the workpiece and the carrier to separate the carrier from the workpiece.

### BACKGROUND OF THE INVENTION

### Field of the Invention

The present invention relates to a method of separating a carrier bonded to a workpiece by a temporary adhesive layer from the workpiece and a method of manufacturing packaged devices from such a workpiece.

### Description of the Related Art

Device chips that include such devices as electronic circuits, for example, are indispensable components in electronic appliances, typically, cellular phones and personal computers. Device chips are manufactured by constructing a plurality of devices in a matrix of respective areas on a wafer made of a semiconductor material such as silicon, for example, and then dividing the wafer along the boundaries between the devices.

A device chip thus manufactured is electrically connected to the terminals of a printed circuit board by wire bonding, and then packaged by molded resin, producing a packaged device. The device included in the packaged device is restrained from deterioration attributable to external factors including impact, light, heat, and water.

Packaging may be performed not only on device chips fabricated by dividing a wafer, but also on a wafer itself. In the latter case, packaged devices are manufactured by packaging a wafer with molded resin after a re-distribution layer (RDL) has been formed on the wafer and then dividing the packaged wafer.

A technology called fan-out wafer level packaging (FOWLP) or fan-out panel level packaging (FOPLP) has also been proposed in the art for manufacturing packaged devices where the size of a re-distribution layer is larger than the size of a device chip due to trends toward higher circuit integration in recent years (see, for example, JP 2016-201519A). The proposed technology is based on the temporary use of a carrier such as the wafer referred to above or a panel, typically, a glass panel used to manufacture a flat panel display.

Specifically, according to the technology, after a re-distribution layer has been formed on a carrier with a temporary adhesive layer interposed therebetween, a plurality of device chips are bonded to the re-distribution layer. Then, the device chips are encapsulated by molded resin to produce a wafer-shaped or panel-shaped structure, i.e., workpiece, that includes the re-distribution layer, the device chips, and the molded resin, after which the carrier is separated from the workpiece. The workpiece is then divided into a plurality of packaged devices.

Alternatively, after a plurality of device chips have been bonded to a carrier by a temporary adhesive layer, the device chips are encapsulated by molded resin to produce a wafer-shaped or panel-shaped structure, i.e., workpiece, that includes the device chips and the molded resin. Then, the carrier is separated from the workpiece, after which a re-distribution layer is formed on the workpiece. The workpiece is then divided into a plurality of packaged devices.

### SUMMARY OF THE INVENTION

To separate the carrier from the workpiece, external forces are applied to the carrier and the workpiece to pull them apart. However, if the bonding force of the temporary adhesive layer is too strong, cracks that act as separation initiating points are not developed in the temporary adhesive layer until strong external forces are applied. Once cracks are developed, they tend to extend to the workpiece, possibly causing damage to the workpiece. It is therefore an object of the present invention to provide a method of separating a carrier bonded to a workpiece by a temporary adhesive layer from the workpiece with reduced probability to damage the workpiece.

In accordance with an aspect of the present invention, there is provided a method of separating a carrier bonded to a workpiece by a temporary adhesive layer from the workpiece. The method includes forming a separation initiating point in the temporary adhesive layer by inserting a protrusive member into the temporary adhesive layer in such a manner that the protrusive member enters between the workpiece and the carrier and, after the separation initiating point has been formed in the temporary adhesive layer, applying external forces respectively to the workpiece and the carrier to separate the carrier from the workpiece.

In accordance with another aspect of the present invention, there is provided a method of manufacturing packaged devices from a workpiece bonded to a carrier by a temporary adhesive layer. The method includes forming a separation initiating point in the temporary adhesive layer by inserting a protrusive member into the temporary adhesive layer in such a manner that the protrusive member enters between the workpiece and the carrier, after the separation initiating point has been formed in the temporary adhesive layer, applying external forces respectively to the workpiece and the carrier to separate the carrier from the workpiece, and dividing the workpiece.

According to the present invention, each of the methods should preferably further include, before the separation initiating point is formed in the temporary adhesive layer, removing an outer circumferential portion of one of the workpiece and the carrier to newly expose a surface of an outer circumferential portion of the other of the workpiece and the carrier, and the carrier should preferably be separated from the workpiece by application of a pressing force to the surface of the outer circumferential portion of the other of the workpiece and the carrier to space the other of the workpiece and the carrier from the one of the workpiece and the carrier. The carrier should preferably be separated from the workpiece while fluid is being ejected to the temporary adhesive layer, while the temporary adhesive layer is being immersed in liquid, while the temporary adhesive layer is being immersed in liquid and the pressing force is being applied to apply vibrations to the outer circumferential portion of the other of the workpiece and the carrier, while the temporary adhesive layer is being immersed in liquid and ultrasonic waves are being applied to the liquid in which the temporary adhesive layer is immersed, or while the temporary adhesive layer is being immersed in liquid containing a surfactant.

According to the present invention, moreover, the separation initiating point should preferably be formed in the temporary adhesive layer by repeating a sequence of turning through a predetermined angle the workpiece and the carrier that are integrally combined by the temporary adhesive layer about an axis represented by a straight line which passes through a center of the workpiece and the carrier that are integrally combined by the temporary adhesive layer and which is parallel to thicknesswise directions of the workpiece and the carrier, after the workpiece and the carrier that are integrally combined by the temporary adhesive layer have been turned through the predetermined angle, inserting the protrusive member into the temporary adhesive layer by moving the protrusive member that has been positioned in a predetermined direction as viewed from the center in plan, along a direction opposite the predetermined direction, and, after the protrusive member has been inserted into the temporary adhesive layer, withdrawing the protrusive member from the temporary adhesive layer by moving the protrusive member along the predetermined direction, until the protrusive member is inserted into the temporary adhesive layer a predetermined number of times.

According to the present invention, the separation initiating point is formed in the temporary adhesive layer prior to the separation of the carrier from the workpiece. Even if the bonding force of the temporary adhesive layer is strong, cracks can be developed progressively from the separation initiating point into the temporary adhesive layer by application of a relatively weak external force to the temporary adhesive layer. As a result, the methods according to the present invention make it possible to reduce the probability of damage to the workpiece at the time when the carrier is separated from the workpiece.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1A is a perspective view schematically illustrating by way of example a layered assembly including a workpiece and a carrier that are integrally combined with each other by a temporary adhesive layer;

FIG. 1B is a cross-sectional view schematically illustrating the layered assembly illustrated in FIG. 1A;

FIG. 2 is a flowchart schematically illustrating by way of example a method of separating the carrier from the workpiece of the layered assembly illustrated in FIGS. 1A and 1B;

FIG. 3 is a flowchart schematically illustrating by way of example a separation initiating point forming step of the method illustrated in FIG. 2;

FIG. 4A is a plan view schematically illustrating by way of example a position adjusting step illustrated in FIG. 3;

FIG. 4B is a cross-sectional view taken along line IVB-IVB of FIG. 4A;

FIG. 5A is a plan view schematically illustrating by way of example an inserting step illustrated in FIG. 3;

FIG. 5B is a cross-sectional view taken along line VB-VB of FIG. 5A;

FIG. 6A is a plan view schematically illustrating by way of example a withdrawing step illustrated in FIG. 3;

FIG. 6B is a cross-sectional view taken along line VIB-VIB of FIG. 6A;

FIG. 7A is a plan view schematically illustrating by way of example a rotating step illustrated in FIG. 3;

FIG. 7B is a cross-sectional view taken along line VIIB-VIIB of FIG. 7A;

FIG. 8A is a side elevational view, partly in cross section, schematically illustrating by way of example a carrier separating step of the method illustrated in FIG. 2;

FIG. 8B is a side elevational view, partly in cross section, schematically illustrating by way of example the carrier separating step of the method illustrated in FIG. 2;

FIG. 9 is a flowchart schematically illustrating by way of example another method of separating the carrier from the workpiece of the layered assembly illustrated in FIGS. 1A and 1B;

FIG. 10A is a side elevational view, partly in cross section, schematically illustrating by way of example an outer circumferential portion removing step of the method illustrated in FIG. 9;

FIG. 10B is a cross-sectional view schematically illustrating the layered assembly after the outer circumferential portion removing step illustrated in FIG. 10A;

FIG. 11A is a side elevational view, partly in cross section, schematically illustrating by way of example another carrier separating step different from the carrier separating step illustrated in FIGS. 8A and 8B;

FIG. 11B is a side elevational view, partly in cross section, schematically illustrating by way of example still another carrier separating step different from the carrier separating step illustrated in FIGS. 8A and 8B;

FIG. 11C is a side elevational view, partly in cross section, schematically illustrating by way of example yet another carrier separating step different from the carrier separating step illustrated in FIGS. 8A and 8B; and

FIG. 12 is a flowchart schematically illustrating by way of example a method of manufacturing packaged devices from the workpiece of the layered assembly illustrated in FIGS. 1A and 1B.

### DETAILED DESCRIPTION OF THE PREFERRED EMBODIMENTS

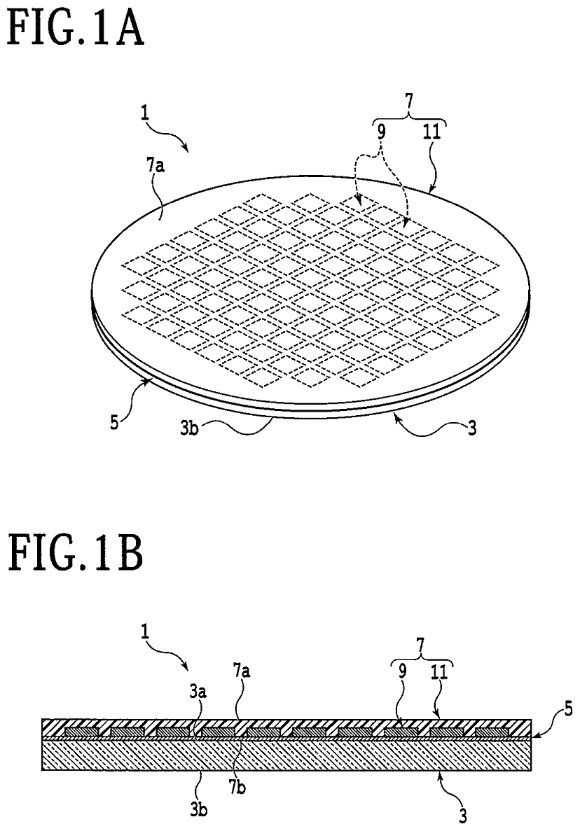

Preferred embodiments of the present invention will be described in detail below with reference to the accompanying drawings. FIG. 1A schematically illustrates in perspective by way of example a layered assembly including a workpiece and a carrier that are integrally combined with each other by a temporary adhesive layer. FIG. 1B schematically illustrates in cross section the layered assembly illustrated in FIG. 1A. As illustrated in FIGS. 1A and 1B, the layered assembly, denoted by 1, includes a disk-shaped carrier 3.

The carrier 3 is a wafer made of a semiconductor such as silicon, for example. The carrier 3 has a thickness equal to or smaller than 2.0 mm, typically of 1.1 mm, for example. Stated otherwise, the carrier 3 has a face side 3a and a reverse side 3b, each of a circular shape, that are spaced from each other by a distance equal to or smaller than 2.0 mm, typically of 1.1 mm, for example.

The layered assembly 1 includes a disk-shaped temporary adhesive layer 5 that is disposed on the face side 3a of the carrier 3 and that fully covers the face side 3a in its entirety. The adhesive layer 5 has a thickness equal to or smaller than 20 μm, typically of 5.0 μm, for example. The temporary adhesive layer 5 is made of resin functioning as an adhesive. The temporary adhesive layer 5 bonds the carrier 3 and a disk-shaped workpiece 7 to each other.

The workpiece 7 has a thickness equal to or smaller than 1.5 mm, typically of 0.6 mm, for example. Stated otherwise, the workpiece 7 has a face side 7a and a reverse side 7b, each of a circular shape, that are spaced from each other by a distance equal to or smaller than 1.5 mm, typically of 0.6 mm, for example. The face side 7a faces away from the temporary adhesive layer 5, whereas the reverse side 7b faces toward the temporary adhesive layer 5. The face side 7a of the workpiece 7 may have been ground in advance.

The workpiece 7 includes a matrix of device chips 9 and molded resin 11 encapsulating the device chips 9. The workpiece 7 may also include an unillustrated re-distribution layer disposed between the temporary adhesive layer 5 and the device chips 9 encapsulated by the molded resin 11.

The layered assembly 1 may include a rectangular carrier in place of the disk-shaped carrier 3. The rectangular carrier is a panel made of glass that mainly contains silicon dioxide, for example. If the rectangular carrier is incorporated in the layered assembly 1, then the temporary adhesive layer 5 and the workpiece 7 are each of a rectangular shape that is commensurate with the rectangular carrier as viewed in plan.

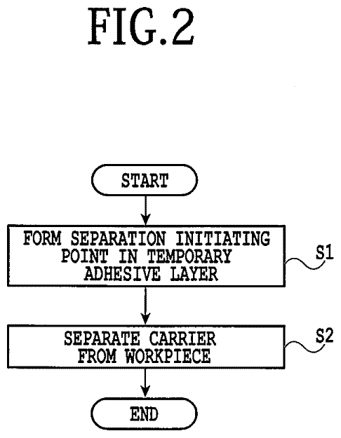

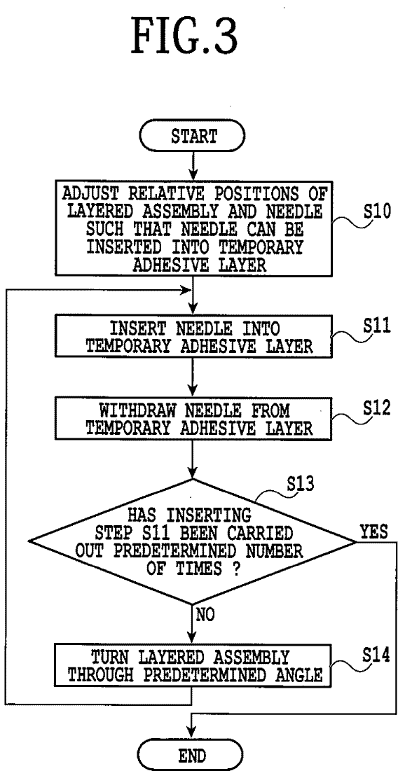

FIG. 2 is a flowchart schematically illustrating by way of example a method of separating the carrier 3 from the workpiece 7 of the layered assembly 1 illustrated in FIGS. 1A and 1B. According to the method illustrated in FIG. 2, first, a separation initiating point is formed in the temporary adhesive layer 5 (separation initiating point forming step S1). FIG. 3 is a flowchart schematically illustrating by way of example separation initiating point forming step S1.

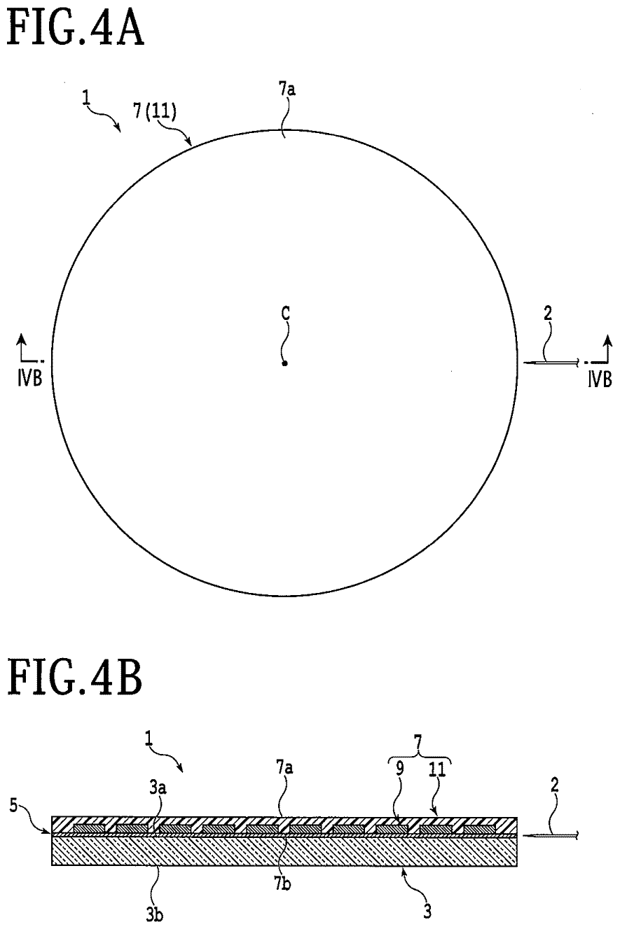

In separation initiating point forming step S1, the relative positions of the layered assembly 1 and a needle to be inserted into the temporary adhesive layer 5 are adjusted such that the needle can be inserted into the temporary adhesive layer 5 (position adjusting step S10). FIG. 4A schematically illustrates in plan by way of example position adjusting step S10, and FIG. 4B is a cross-sectional view taken along line IVB-IVB of FIG. 4A.

In position adjusting step S10, specifically, the relative positions of the layered assembly 1 and the needle, denoted by 2 in FIGS. 4A and 4B, are adjusted in order to position the needle 2 in a predetermined direction as viewed in plan from a center C of the layered assembly 1, e.g., a rightward direction in FIG. 4A. For example, in position adjusting step S10, the layered assembly 1 is moved back and forth, i.e., in upward and downward directions in FIG. 4A, in order to position the center C to the left of the needle 2 as viewed in plan from the needle 2 that extends in leftward and rightward directions in FIG. 4A and that has a pointed end directed to the left. Then, the needle 2 is lifted and lowered, i.e., in upward and downward directions in FIG. 4B, in order to position itself at a height aligned with the temporary adhesive layer 5.

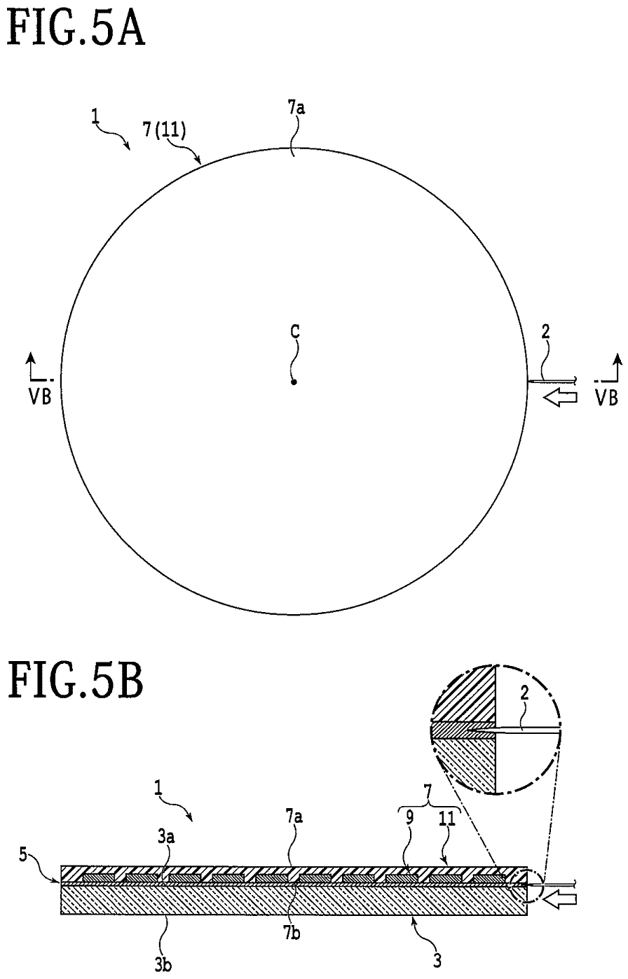

After position adjusting step S10 has been carried out, the needle 2 is inserted into the temporary adhesive layer 5 (inserting step S11). FIG. 5A schematically illustrates in plan by way of example inserting step S11, and FIG. 5B is a cross-sectional view taken along line VB-VB of FIG. 5A.

In inserting step S11, the needle 2 is moved toward the layered assembly 1 in a direction opposite the predetermined direction referred to above, i.e., a leftward direction in FIG. 5A, until the pointed end of the needle 2 is inserted into the temporary adhesive layer 5 from a side face thereof to a predetermined depth in the temporary adhesive layer 5. The predetermined depth is in the range of 0 mm exclusive to 5.0 mm, preferably in the range of 0.1 to 2.0 mm.

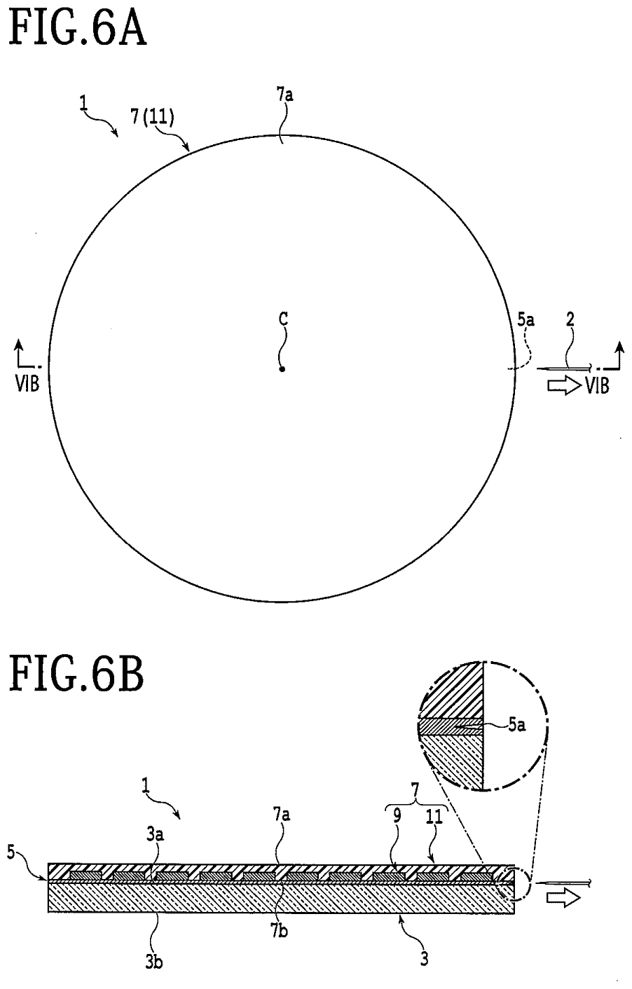

After inserting step S11 has been carried out, the needle 2 is withdrawn from the temporary adhesive layer 5 (withdrawing step S12). FIG. 6A schematically illustrates in plan by way of example withdrawing step S12, and FIG. 6B is a cross-sectional view taken along line VIB-VIB of FIG. 6A.

In withdrawing step S12, the needle 2 is moved in the predetermined direction by the same distance as the distance that the needle 2 has been moved in inserting step S11. The needle 2 is now pulled out of the temporary adhesive layer 5, leaving in the temporary adhesive layer 5 a hole 5a that has been formed therein by the needle 2 inserted in inserting step S11. The hole 5a functions as a separation initiating point in carrier separating step S2 to be described later.

If inserting step S11 has not been carried out a predetermined number n of times (step S1: NO), then the layered assembly 1 is turned through a predetermined angle θ (rotating step S14). The predetermined number n refers to a natural number of 2 or greater. The predetermined angle θ refers to an angle calculated by dividing 360° by the predetermined number n, for example.

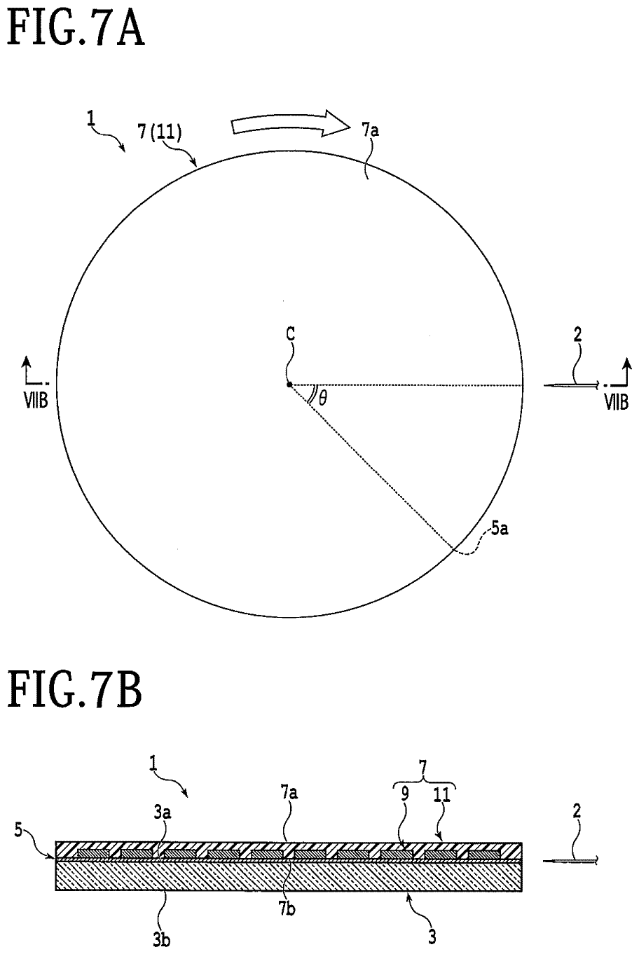

FIG. 7A schematically illustrates in plan by way of example rotating step S14, and FIG. 7B is a cross-sectional view taken along line VIIB-VIIB of FIG. 7A. In rotating step S14, the layered assembly 1 is turned through the predetermined angle θ, e.g., 45°, about its central axis, represented by a straight line, extending through the center C and parallel to thicknesswise directions of the layered assembly 1.

In separation initiating point forming step S1, the sequence of steps including the above-mentioned rotating step S14, inserting step S11 and withdrawing step S12 is repeated the predetermined number n of times, e.g., 8 times. If inserting step S11 has been carried out the predetermined number n of times (step S13: YES), then separation initiating point forming step S1 is completed.

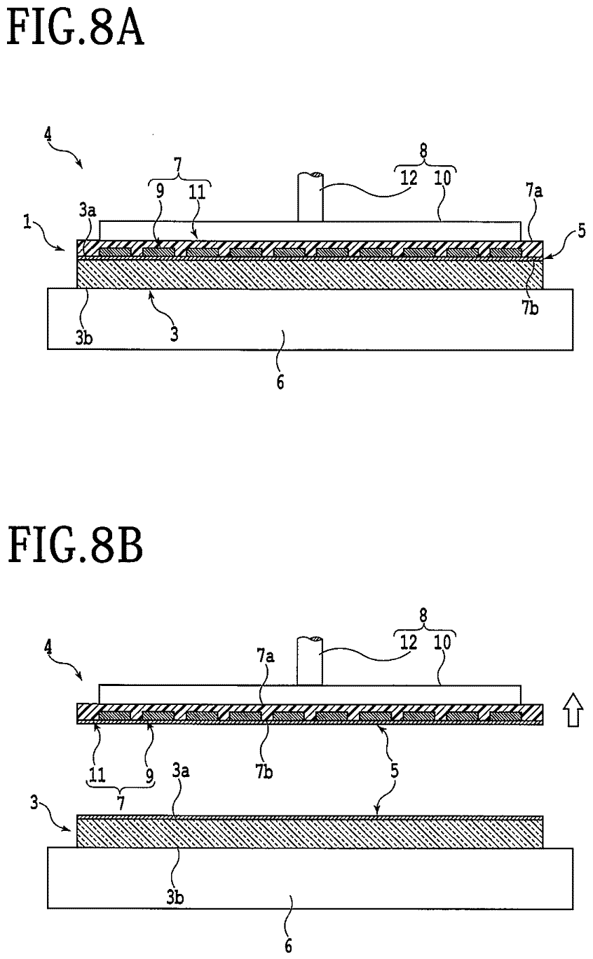

After separation initiating point forming step S1 has been carried out, the carrier 3 is separated from the workpiece 7 (carrier separating step S2). FIGS. 8A and 8B schematically illustrate in side elevation, partly in cross section, by way of example carrier separating step S2.

Carrier separating step S2 is carried out by a separating apparatus 4 (see FIGS. 8A and 8B), for example. The separating apparatus 4 includes a chuck table 6 having a circular upper surface as a holding surface that lies essentially parallel to a horizontal plane. The chuck table 6 is fluidly connected through a fluid channel defined therein to an unillustrated table suction mechanism having a vacuum pump, for example.

When the table suction mechanism is actuated, it generates and transmits a suction force through the fluid channel to the holding surface of the chuck table 6 where the suction force acts in a space near the holding surface. Therefore, if the layered assembly 1 is present on the holding surface when the table suction mechanism is actuated, the layered assembly 1 is held under suction on the holding surface of the chuck table 6.

The separating apparatus 4 also includes a separating unit 8 disposed above the chuck table 6. The separating unit 8 has a suction plate 10 with a plurality of suction holes defined in a lower surface thereof. The suction holes are fluidly connected through a fluid channel defined in the suction plate 10 to an unillustrated separating unit suction mechanism including a vacuum pump, for example. When the separating unit suction mechanism is actuated, it generates and transmits a suction force to the suction plate 10 where the suction force acts in a space near the lower surface thereof through the suction holes.

The separating unit 8 also has a vertically moving mechanism 12 coupled to an upper surface of the suction plate 10. The vertically moving mechanism 12 includes, for example, a ball screw and an electric motor, both of which are not illustrated. When the vertically moving mechanism 12 is actuated, it moves the suction plate 10 vertically.

The separating apparatus 4 performs carrier separating step S2 as follows: With the chuck table 6 and the suction plate 10 being widely spaced from each other, the layered assembly 1 where the hole 5a has been formed in the temporary adhesive layer 5 is placed on the holding surface of the chuck table 6 such that the workpiece 7 lies over the carrier 3. Then, the table suction mechanism is actuated to hold the carrier 3 under suction on the holding surface of the chuck table 6.

Subsequently, the vertically moving mechanism 12 lowers the suction plate 10 in order to bring the lower surface of the suction plate 10 into contact with the face side 7a of the workpiece 7 (see FIG. 8A). The separating unit suction mechanism is actuated to attract the workpiece 7 of the layered assembly 1 upwardly. Then, the vertically moving mechanism 12 lifts the suction plate 10 away from the chuck table 6 (see FIG. 8B).

Consequently, external forces, specifically, suction forces, are applied to the carrier 3 and the workpiece 7 to separate them from each other. As a result, cracks are developed from the hole 5a in the temporary adhesive layer 5 into the temporary adhesive layer 5, cleaving the layered assembly 1 at the temporary adhesive layer 5. In other words, the carrier 3 is separated from the workpiece 7 from the hole 5a formed as a separation initiating point in the temporary adhesive layer 5. Carrier separating step S2 is now completed, i.e., the method of separating a carrier illustrated in FIG. 2 is completed.

According to the method of separating a carrier illustrated in FIG. 2, the hole 5a is formed in the temporary adhesive layer 5 as a separation initiating point prior to the separation of the carrier 3 from the workpiece 7. With the hole 5a being present in the temporary adhesive layer 5, even if the bonding force of the temporary adhesive layer 5 is strong, cracks can be developed progressively from the hole 5a into the temporary adhesive layer 5 by application of a relatively weak external force to the temporary adhesive layer 5. As a result, the method of separating a carrier makes it possible to reduce the probability of damage to the workpiece 7 at the time when the carrier 3 is separated from the workpiece 7.

The details of the present embodiment have been described above by way of example only. The present invention is not limited to the above details. Though the needle 2 is used to form a separation initiating point in the temporary adhesive layer 5 according to the above embodiment, anything protrusive that is capable of forming a separation initiating point in the temporary adhesive layer 5 may be used in place of the needle 2 in separation initiating point forming step S1. For example, a wedge or a structure having a needle-shaped portion or a wedge-shaped portion may be used instead of the needle 2.

Moreover, according to the present invention, a needle that is inclined to the predetermined direction referred to above may be used in separation initiating point forming step S1. Specifically, a needle inclined to peel off an outer circumferential portion of the workpiece 7 locally from an outer circumferential portion of the carrier 3 upon insertion into the temporary adhesive layer 5 may be used in separation initiating point forming step S1, specifically, in inserting step S11.

For example, in separation initiating point forming step S1, a needle may have a proximal end positioned slightly higher than the needle 2 illustrated in FIGS. 4B, 5B, 6B, and 7B while keeping its pointed end unchanged in position. When the needle with the slightly higher proximal end is inserted into the temporary adhesive layer 5 in inserting step S11, the needle applies external forces tending to peel off the outer circumferential portion of the workpiece 7 from the outer circumferential portion of the carrier 3. As a consequence, the outer circumferential portion of the workpiece 7 can be peeled off locally from the outer circumferential portion of the carrier 3.

Further, carrier separating step S2 may be carried out while the layered assembly 1 is in a vertically reversed state. Specifically, carrier separating step S2 may be carried out while the workpiece 7 of the layered assembly 1 is being attracted under suction to the holding surface of the chuck table 6 and the carrier 3 of the layered assembly 1 is being attracted under suction to the lower surface of the suction plate 10.

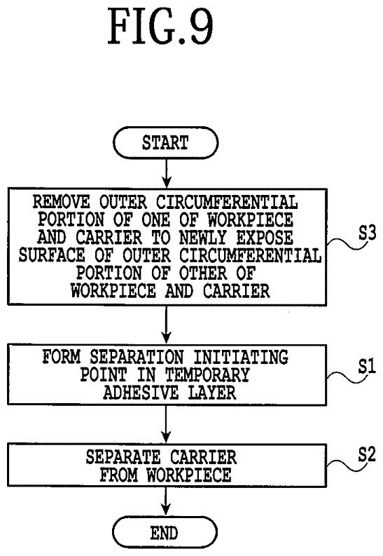

According to the present invention, prior to separation initiating point forming step S1, the layered assembly 1 may be processed to facilitate the separation of the carrier 3 from the workpiece 7 in carrier separating step S2. FIG. 9 is a flowchart schematically illustrating by way of example such another method of separating the carrier 3 from the workpiece 7.

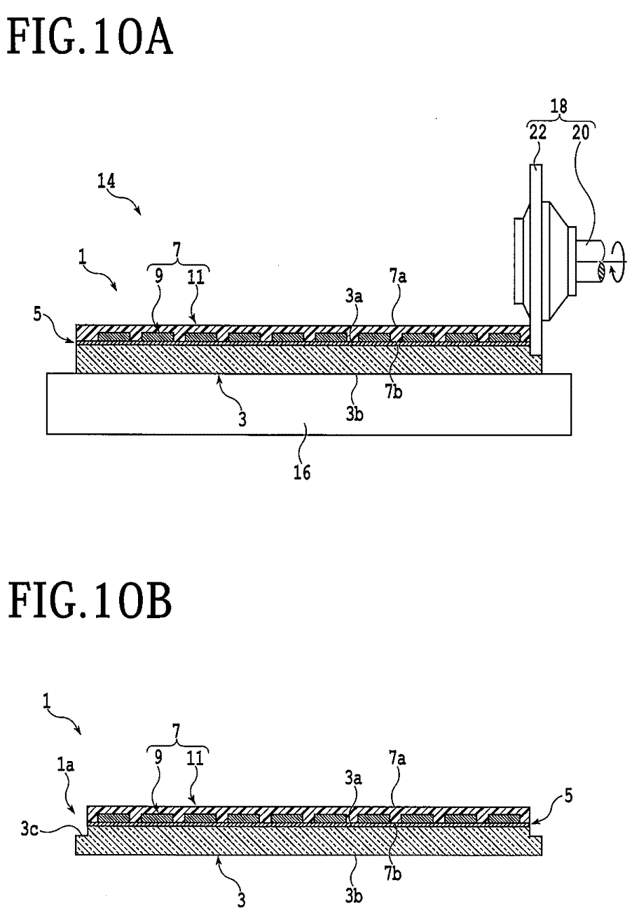

According to the method of separating the carrier 3 from the workpiece 7 illustrated in FIG. 9, before separation initiating point forming step S1 is carried out, an outer circumferential portion of one of the workpiece 7 and the carrier 3 is removed to newly expose a surface of an outer circumferential portion of the other of the workpiece 7 and the carrier 3 (outer circumferential portion removing step S3). FIG. 10A schematically illustrates in side elevation, partly in cross section, by way of example outer circumferential portion removing step S3. FIG. 10B schematically illustrates in side elevation, partly in cross section, by way of example the layered assembly 1 after outer circumferential portion removing step S3 illustrated in FIG. 10A.

Outer circumferential portion removing step S3 is carried out by a cutting apparatus 14 (see FIG. 10A). The cutting apparatus 14 includes a chuck table 16 having a circular upper surface as a holding surface that lies essentially parallel to a horizontal plane. The chuck table 16 is fluidly connected through a fluid channel defined therein to an unillustrated suction mechanism having an ejector, for example, and is coupled to an unillustrated rotating mechanism having a pulley and an electric motor, for example, and an unillustrated first horizontally moving mechanism having a ball screw and an electric motor, for example.

When the suction mechanism is actuated, it generates and transmits a suction force through the fluid channel to the holding surface of the chuck table 16 where the suction force acts in a space near the holding surface. Therefore, if the layered assembly 1 is present on the holding surface when the suction mechanism is actuated, the layered assembly 1 is held under suction on the holding surface. When the rotating mechanism is actuated, it rotates the chuck table 16 about its central axis, represented by a straight line, extending vertically through the center of the holding surface. When the first horizontally moving mechanism is actuated, it moves the chuck table 16 along a first horizontal direction, i.e., a processing feed direction, parallel to the holding surface of the chuck table 16.

The cutting apparatus 14 also includes a cutting unit 18 disposed above the chuck table 16. The cutting unit 18 has a spindle 20 extending parallel to the holding surface of the chuck table 16 and along a second horizontal direction, i.e., an indexing feed direction, perpendicular to the first horizontal direction. The spindle 20 has a proximal end coupled to an unillustrated electric motor for rotating the spindle 20 about its central axis. The cutting unit 18 further has an annular cutting blade 22 mounted on a distal end of the spindle 20.

When the electric motor coupled to the spindle 20 is energized, it rotates the spindle 20 and the cutting blade 22 about their central axis represented by a straight line parallel to the second horizontal direction. The cutting blade 22 has a width or thickness, i.e., a length along the second horizontal direction, in the range of 0.2 to 5 mm. The spindle 20 is coupled to an unillustrated second horizontally moving mechanism and an unillustrated vertically moving mechanism each having a ball screw and an electric motor, for example.

When the second horizontally moving mechanism is actuated, it moves the spindle 20 and the cutting blade 22 along the second horizontal direction. When the vertically moving mechanism is actuated, it moves the spindle 20 and the cutting blade 22 along vertical directions, i.e., selectively lifts and lowers the spindle 20 and the cutting blade 22.

The cutting apparatus 14 carries out outer circumferential portion removing step S3 as follows: First, the layered assembly 1 is placed on the holding surface of the chuck table 16 with the workpiece 7 lying over the carrier 3. Then, the suction mechanism is actuated to hold the carrier 3 of the layered assembly 1 under suction on the holding surface of the chuck table 16.

Thereafter, in order to position the cutting blade 22 directly above an end of the layered assembly 1 in the second horizontal direction, the first horizontally moving mechanism moves the chuck table 16 along the first horizontal direction, and/or the second horizontally moving mechanism and/or the vertically moving mechanism move/moves the spindle 20 along the second horizontal direction and/or the vertical directions.

Then, the electric motor coupled to the proximal end of the spindle 20 is energized to rotate the cutting blade 22 about its central axis. While the cutting blade 22 is in rotation, the vertically moving mechanism lowers the spindle 20 until the lower end of the cutting blade 22 is brought into a position that is lower than the face side 3a of the carrier 3 but higher than the reverse side 3b thereof (see FIG. 10A).

Then, while the cutting blade 22 is still in rotation, the rotating mechanism coupled to the chuck table 16 is energized to rotate the chuck table 16 and hence the layered assembly 1 thereon such that they make at least one revolution. The cutting blade 22 now removes the outer circumferential portion of the workpiece 7 and the face side 3a of the outer circumferential portion of the carrier 3. As a result, a surface 3c of the outer circumferential portion of the carrier 3 is newly exposed, as illustrated in FIG. 10B. Stated otherwise, a step 1a including a lower step face provided by the surface 3c and an upper step face provided by the face side 7a of the workpiece 7 is formed in an outer circumferential portion of the layered assembly 1.

In outer circumferential portion removing step S3, the layered assembly 1 may alternatively be processed to remove the outer circumferential portion of the carrier 3 and the reverse side 7b of the outer circumferential portion of the workpiece 7. In this case, outer circumferential portion removing step S3 is carried out in the manner described above except that the layered assembly 1 is placed on the holding surface of the chuck table 16 with the carrier 3 lying over the workpiece 7 and the workpiece 7 is held under suction on the holding surface of the chuck table 16.

Separation initiating point forming step S1 is carried out on the layered assembly 1 where the step 1a has been formed, in the same manner as that of separation initiating point forming step S1 illustrated in FIG. 3. The needle 2 used in separation initiating point forming step S1 may be coupled to the spindle 20 of the cutting apparatus 14, and separation initiating point forming step S1 may be carried out by the cutting apparatus 14.

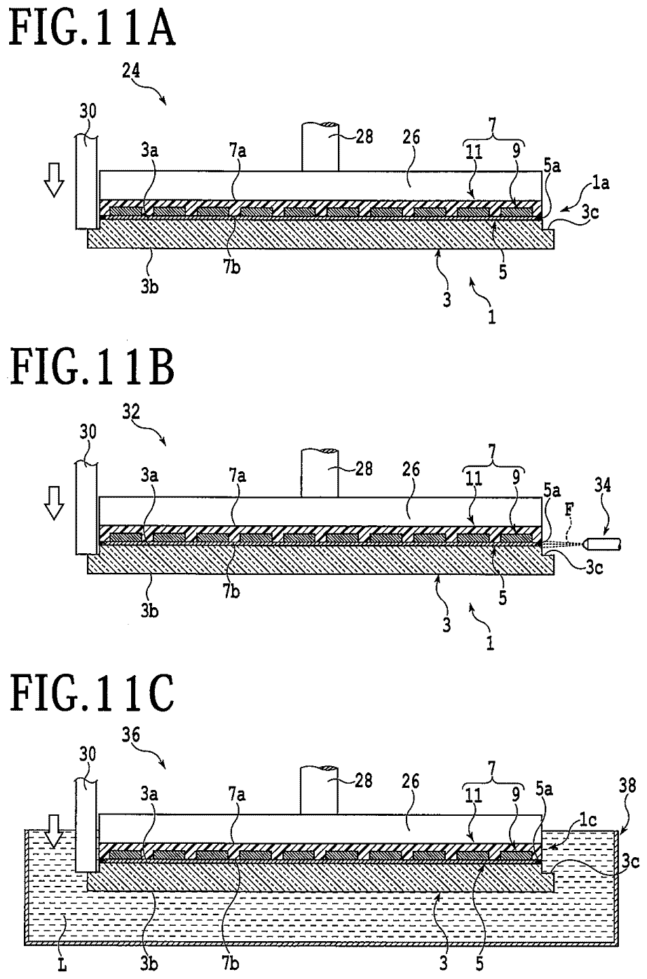

Carrier separating step S2 is carried out on the layered assembly 1 where the step 1a has been formed and the hole 5a has been formed in the temporary adhesive layer 5, in the same manner as that of carrier separating step S2 illustrated in FIGS. 8A and 8B. Alternatively, carrier separating step S2 may be carried out in a different manner. FIGS. 11A, 11B, and 11C schematically illustrate in side elevation, partly in cross section, by way of example other carrier separating steps, each also denoted by S2, different from carrier separating step S2 illustrated in FIGS. 8A and 8B.

Carrier separating step S2 illustrated in FIG. 11A is carried out by a separating apparatus 24. The separating apparatus 24 includes a holding plate 26 having a circular lower surface as a holding surface that lies essentially parallel to a horizontal plane. The holding plate 26 is fluidly connected through a fluid channel defined therein to an unillustrated suction mechanism having an ejector, for example. The holding plate 26 is also coupled to a first lifting and lowering mechanism 28 having a ball screw and an electric motor, for example.

The separating apparatus 24 further includes a presser bar 30 disposed sideways of the holding plate 26. The presser bar 30 is vertically movable and horizontally located in a position immediately above at least a region of the surface 3c of the outer circumferential portion of the carrier 3 at the time when the workpiece 7 of the layered assembly 1 is held on the holding surface of the holding plate 26. The presser bar 30 is coupled to an unillustrated second lifting and lowering mechanism having a ball screw and an electric motor, for example.

The separating apparatus 24 carries out carrier separating step S2 as follows: First, the first lifting and lowering mechanism 28 lowers the holding plate 26 to bring the holding surface of the holding plate 26 into contact with the face side 7a of the workpiece 7. Then, the suction mechanism fluidly coupled to the holding plate 26 is actuated to hold the workpiece 7 of the layered assembly 1 under suction on the holding surface of the holding plate 26.

Then, the first lifting and lowering mechanism 28 is actuated to lift the holding plate 26, lifting and positioning the layered assembly 1 at a predetermined height where the carrier 3 is exposed downwardly. While the layered assembly 1 is being kept at the predetermined height, the second lifting and lowering mechanism is actuated to lower the presser bar 30 and press a lower end surface of the presser bar 30 against the surface 3c of the outer circumferential portion of the carrier 3.

At this time, external forces are applied to the carrier 3 and the workpiece 7 to separate them from each other. Specifically, a pressing force is applied to the carrier 3 whereas a suction force is applied to the workpiece 7. As a result, cracks are developed from the hole 5a in the temporary adhesive layer 5 into the temporary adhesive layer 5, cleaving the layered assembly 1 at the temporary adhesive layer 5. In other words, the carrier 3 is separated from the workpiece 7 from the hole 5a formed as a separation initiating point in the temporary adhesive layer 5.

Carrier separating step S2 illustrated in FIG. 11B is carried out by a separating apparatus 32. The separating apparatus 32 includes a nozzle 34 in addition to the components of the separating apparatus 24 illustrated in FIG. 11A. The nozzle 34 is oriented toward the temporary adhesive layer 5 of the layered assembly 1 whose workpiece 7 is held on the holding surface of the holding plate 26 and that is positioned at the predetermined height. The nozzle 34 is fluidly connected to an unillustrated fluid supply source via an unillustrated pipe and an unillustrated valve. When the valve is opened and the fluid supply source is actuated, the nozzle 34 ejects fluid F, e.g., gas such as air or liquid such as water, supplied from the fluid supply source via the pipe and the valve toward the temporary adhesive layer 5.

The separating apparatus 32 carries out carrier separating step S2 as follows: First, the holding plate 26 is operated to position the layered assembly 1 at the predetermined height in the same manner as that of the separating apparatus 24 carrying out carrier separating step S2. Then, while the layered assembly 1 is being kept at the predetermined height, the second lifting and lowering mechanism is actuated to lower the presser bar 30 and press the lower end surface of the presser bar 30 against the surface 3c of the outer circumferential portion of the carrier 3. At the same time, the nozzle 34 ejects the fluid F toward the temporary adhesive layer 5. Since the fluid F ejected from the nozzle 34 forcibly enters the hole 5a in the temporary adhesive layer 5, the separating apparatus 32 separates the carrier 3 more easily from the workpiece 7 than the separating apparatus 24 as it carries out carrier separating step S2.

Carrier separating step S2 illustrated in FIG. 11C is carried out by a separating apparatus 36. The separating apparatus 36 includes a liquid receptacle 38 in addition to the components of the separating apparatus 24 illustrated in FIG. 11A. The liquid receptacle 38 is an upwardly open bottomed cuboid-shaped hollow structure and is of a size large enough to accommodate the layered assembly 1 therein. The liquid receptacle 38 is coupled to an unillustrated moving mechanism for moving the liquid receptacle 38 between a position directly below the holding plate 26 that holds the workpiece 7 of the layered assembly 1 on the holding surface and a position horizontally spaced from the holding plate 26.

The separating apparatus 36 carries out carrier separating step S2 as follows: First, the holding plate 26 is operated to position the layered assembly 1 at the predetermined height in the same manner as that of the separating apparatus 24 carrying out carrier separating step S2. Then, the moving mechanism moves the liquid receptacle 38 to the position directly below the holding plate 26. Thereafter, the liquid receptacle 38 is filled with liquid L.

The liquid L may contain a surfactant. The surfactant may be, for example, an anionic surfactant or a cationic surfactant that finds it easy to enter the temporary adhesive layer 5. In a case where the liquid L contains a surfactant, the development of cracks in the temporary adhesive layer 5 is promoted. Consequently, it becomes easier to separate the carrier 3 from the workpiece 7 than if the liquid L contains no surfactant.

Then, the first lifting and lowering mechanism 28 is actuated to lower the holding plate 26 into the liquid receptacle 38 until at least the temporary adhesive layer 5 is immersed in the liquid L. Then, while the temporary adhesive layer 5 is being immersed in the liquid L, the second lifting and lowering mechanism is actuated to lower the presser bar 30 and press the lower end surface of the presser bar 30 against the surface 3c of the outer circumferential portion of the carrier 3. The carrier 3 is now separated from the workpiece 7. At this time, the carrier 3 that has been separated from the workpiece 7 drops gradually in the liquid L. Therefore, the carrier 3 is less probable to be damaged upon hitting the bottom of the liquid receptacle 38 than if the carrier 3 separated from the workpiece 7 drops in air.

When the lower end surface of the presser bar 30 is pressed against the surface 3c of the outer circumferential portion of the carrier 3, the separating apparatus 36 may apply ultrasonic waves to the presser bar 30 to ultrasonically vibrate the presser bar 30. Moreover, ultrasonic waves may be applied to the liquid L in addition to or instead of the presser bar 30. The ultrasonic waves thus applied to the presser bar 30 and/or the liquid L are effective to separate the carrier 3 from the workpiece 7 more easily than if the presser bar 30 is not ultrasonically vibrated and ultrasonic waves are not applied to the liquid L.

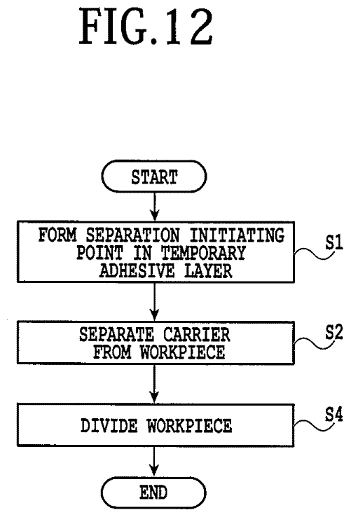

The principles of the present invention are also applicable to a method of manufacturing packaged devices from the workpiece 7 of the layered assembly 1. FIG. 12 is a flowchart schematically illustrating by way of example the method of manufacturing packaged devices from the workpiece 7 of the layered assembly 1 illustrated in FIGS. 1A and 1B. According to the method of manufacturing packaged devices, the workpiece 7 is divided after separation initiating point forming step S1 and carrier separating step S2 have been carried out (dividing step S4).

Specifically, in dividing step S4, the workpiece 7 is processed to remove portions of the workpiece 7 that are positioned at the boundaries between the device chips 9, leaving other unremoved portions as packaged devices including the respective device chips 9. In this manner, the packaged devices are manufactured from the workpiece 7.

Dividing step S4 is carried out by a known processing apparatus such as a cutting apparatus or a laser processing apparatus, for example. For example, dividing step S4 may be carried out by a cutting apparatus that has an annular cutting blade for cutting, while rotating about its central axis, into the workpiece 7 along the boundaries. Alternatively, dividing step S4 may be carried out by a laser processing apparatus that applies a laser beam having a wavelength absorbable by the workpiece 7 to the workpiece 7 along the boundaries.

The structural and methodical details and features according to the above embodiments can be changed or modified without departing from the scope of the invention.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A method of separating a carrier bonded to a workpiece by a temporary adhesive layer from the workpiece, comprising:
forming a separation initiating point in the temporary adhesive layer by inserting a protrusive member into the temporary adhesive layer in such a manner that the protrusive member enters between the workpiece and the carrier; and
after the separation initiating point has been formed in the temporary adhesive layer, applying external forces respectively to the workpiece and the carrier to separate the carrier from the workpiece.

2. The method according to claim 1, further comprising:
before the separation initiating point is formed in the temporary adhesive layer, removing an outer circumferential portion of one of the workpiece and the carrier to newly expose a surface of an outer circumferential portion of the other of the workpiece and the carrier,
wherein the carrier is separated from the workpiece by application of a pressing force to the surface of the outer circumferential portion of the other of the workpiece and the carrier to space the other of the workpiece and the carrier from the one of the workpiece and the carrier.

3. The method according to claim 2,
wherein the carrier is separated from the workpiece while fluid is being ejected to the temporary adhesive layer.

4. The method according to claim 2,
wherein the carrier is separated from the workpiece while the temporary adhesive layer is being immersed in liquid.

5. The method according to claim 2,
wherein the carrier is separated from the workpiece while the temporary adhesive layer is being immersed in liquid and the pressing force is being applied to apply vibrations to the outer circumferential portion of the other of the workpiece and the carrier.

6. The method according to claim 2,
wherein the carrier is separated from the workpiece while the temporary adhesive layer is being immersed in liquid and ultrasonic waves are being applied to the liquid in which the temporary adhesive layer is immersed.

7. The method according to claim 2,
wherein the carrier is separated from the workpiece while the temporary adhesive layer is being immersed in liquid containing a surfactant.

8. The method according to claim 1,
wherein the separation initiating point is formed in the temporary adhesive layer by repeating a sequence of
turning through a predetermined angle the workpiece and the carrier that are integrally combined by the temporary adhesive layer about an axis represented by a straight line which passes through a center of the workpiece and the carrier that are integrally combined by the temporary adhesive layer and which is parallel to thicknesswise directions of the workpiece and the carrier,
after the workpiece and the carrier that are integrally combined by the temporary adhesive layer have been turned through the predetermined angle, inserting the protrusive member into the temporary adhesive layer by moving the protrusive member that has been positioned in a predetermined direction as viewed from the center in plan, along a direction opposite the predetermined direction, and,
after the protrusive member has been inserted into the temporary adhesive layer, withdrawing the protrusive member from the temporary adhesive layer by moving the protrusive member along the predetermined direction,
until the protrusive member is inserted into the temporary adhesive layer a predetermined number of times.

9. A method of manufacturing packaged devices from a workpiece bonded to a carrier by a temporary adhesive layer, comprising:
forming a separation initiating point in the temporary adhesive layer by inserting a protrusive member into the temporary adhesive layer in such a manner that the protrusive member enters between the workpiece and the carrier;
after the separation initiating point has been formed in the temporary adhesive layer, applying external forces respectively to the workpiece and the carrier to separate the carrier from the workpiece; and
dividing the workpiece.

10. The method according to claim 9, further comprising:
before the separation initiating point is formed in the temporary adhesive layer, removing an outer circumferential portion of one of the workpiece and the carrier to newly expose a surface of an outer circumferential portion of the other of the workpiece and the carrier,
wherein the carrier is separated from the workpiece by application of a pressing force to the surface of the outer circumferential portion of the other of the workpiece and the carrier to space the other of the workpiece and the carrier from the one of the workpiece and the carrier.

11. The method according to claim 10,
wherein the carrier is separated from the workpiece while fluid is being ejected to the temporary adhesive layer.

12. The method according to claim 10,
wherein the carrier is separated from the workpiece while the temporary adhesive layer is being immersed in liquid.

13. The method according to claim 10,
wherein the carrier is separated from the workpiece while the temporary adhesive layer is being immersed in liquid and the pressing force is being applied to apply vibrations to the outer circumferential portion of the other of the workpiece and the carrier.

14. The method according to claim 10,
wherein the carrier is separated from the workpiece while the temporary adhesive layer is being immersed in liquid and ultrasonic waves are being applied to the liquid in which the temporary adhesive layer is immersed.

15. The method according to claim 10,
wherein the carrier is separated from the workpiece while the temporary adhesive layer is being immersed in liquid containing a surfactant.

16. The method according to claim 9,
wherein the separation initiating point is formed in the temporary adhesive layer by repeating a sequence of
turning through a predetermined angle the workpiece and the carrier that are integrally combined by the temporary adhesive layer about an axis represented by a straight line which passes through a center of the workpiece and the carrier that are integrally combined by the temporary adhesive layer and which is parallel to thicknesswise directions of the workpiece and the carrier,
after the workpiece and the carrier that are integrally combined by the temporary adhesive layer have been turned through the predetermined angle, inserting the protrusive member into the temporary adhesive layer by moving the protrusive member that has been positioned in a predetermined direction as viewed from the center in plan, along a direction opposite the predetermined direction, and,
after the protrusive member has been inserted into the temporary adhesive layer, withdrawing the protrusive member from the temporary adhesive layer by moving the protrusive member along the predetermined direction,
until the protrusive member is inserted into the temporary adhesive layer a predetermined number of times.
